(19) United States
(12) Patent Application Publication
(10) Pub. No.: US 2024/0255592 A1
(43) Pub. Date: Aug. 1, 2024

(54) REDUCING ANGLE ERROR IN ANGLE SENSOR DUE TO ORTHOGONALITY DRIFT OVER MAGNETIC-FIELD

(71) Applicant: Allegro MicroSystems, LLC, Manchester, NH (US)

(72) Inventors: Samridh Jaiswal, London (GB); Paolo Campiglio, Arcueil (FR); Ronald Lehndorff, Mainz (DE); Yen Ting Liu, Hsinchu City (TW)

(73) Assignee: Allegro MicroSystems, LLC, Manchester, NH (US)

(21) Appl. No.: 18/161,145

(22) Filed: Jan. 30, 2023

(51) Int. Cl. G01R 33/09; G01B 7/30

(52) U.S. Cl. CPC G01R 33/091; G01B 7/30; G01R 33/093; G01R 33/096; G01R 33/098

(57) ABSTRACT

In one aspect, a method includes manufacturing a magnetic-field angle sensor on a wafer. The manufacturing includes forming a cosine bridge that includes forming a first magnetoresistance (MR) element. The manufacturing also includes forming a sine bridge that includes forming a second MR element. Forming the first MR element includes using a process to reduce orthogonality errors between the sine bridge and the cosine bridge caused by anisotropy present in magnetic material in the first MR element.

### BACKGROUND

A magnetic-field sensing element is used to describe a variety of electronic elements that can sense a magnetic field. The magnetic-field sensing element can be, but is not limited to, a Hall Effect element, a magnetoresistance (MR) element, or a magnetotransistor. As is also known, there are different types of magnetoresistance elements, for example, a semiconductor magnetoresistance element such as Indium Antimonide (InSb), a giant magnetoresistance (GMR) element, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

A magnetic-field angle sensor includes one or more magnetic-field sensing elements. In one example, the magnetic-field sensor includes at least two bridges. One bridge is a cosine bridge used to sense changes in a magnetic field in an x-direction. Another bridge is a sine bridge used to sense changes in a magnetic field in a y-direction and the sine bridge is orthogonal to the cosine bridge. In one example, the cosine bridge and the sine bridge each includes at least four MR elements. Any deviation from the orthogonal orientation between the cosine and sine bridges contributes to angle error. Angle errors due to orthogonality drift have been found to be larger as the magnetic field is reduced.

### SUMMARY

In one aspect, a method includes manufacturing a magnetic-field angle sensor on a wafer. The manufacturing includes forming a cosine bridge that includes forming a first magnetoresistance (MR) element. The manufacturing also includes forming a sine bridge that includes forming a second MR element. Forming the first MR element includes using a process to reduce orthogonality errors between the sine bridge and the cosine bridge caused by anisotropy present in magnetic material in the first MR element.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 is a block diagram of an example of a magnetoresistance (MR) element used in an angle sensor;

FIG. 2 is a flowchart of an example of a process used to fabricate an angle sensor with reduced angle errors due to orthogonality drift over a magnetic field;

FIGS. 3A to 3D are particular examples of diagrams depicting wafer orientations for four depositions of antiferromagnetic material and ferromagnetic material;

FIG. 4A is graph of an example of angle error without using the process in FIG. 2;

FIG. 4B is graph of an example of angle error using the process in FIG. 2;

FIG. 5 is a flowchart of another example of a process used to fabricate the angle sensor with reduced angle errors due to orthogonality drift over a magnetic field;

FIG. 6 is a diagram of an example of wafer orientation during material deposition and annealing; and

FIG. 7 is a flowchart of a further example of a process used to fabricate the angle sensor with reduced angle errors due to orthogonality drift over a magnetic field.

### DETAIL DESCRIPTION

Described herein are techniques to fabricate an angle sensor with reduced angle errors than angle sensors fabricated using traditional angle sensor fabrication. The techniques described herein reduce angle errors from orthogonality drift (between a sine bridge and cosine bridge) over a magnetic field caused by anisotropy present in magnetic material (antiferromagnetic material and ferromagnetic material).

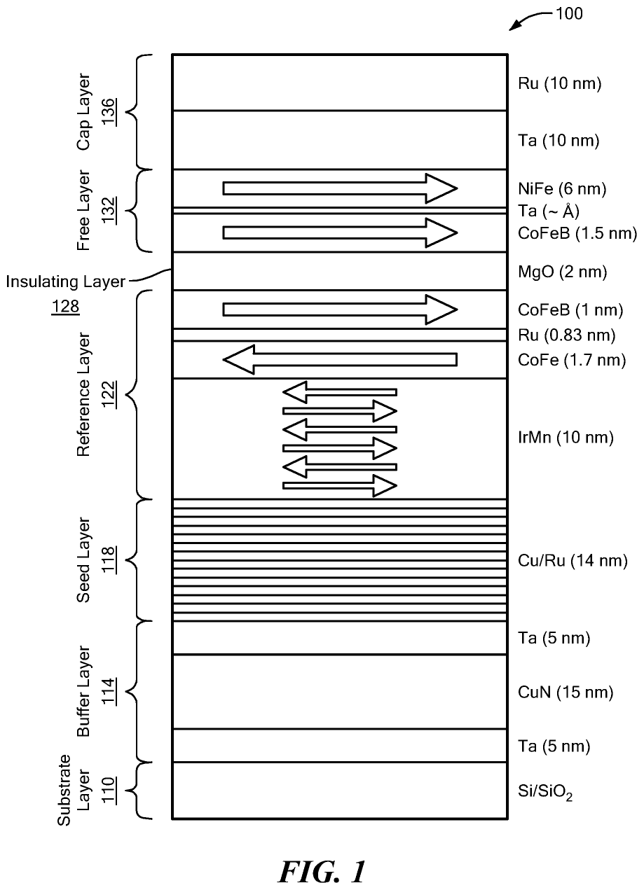

Referring to FIG. 1, an example of a magnetoresistance (MR) element used in an angle sensor is a MR element 100. In this particular example, the MR element is an example of a tunneling magnetoresistance (TMR) element. In other examples, the MR element may be a giant magnetoresistance (GMR) element.

The MR element 100 is arranged in a stack of layers. The MR element 100 includes a substrate layer 110; a buffer layer 114 on the substrate layer 110; a seed layer 118 on the buffer layer 114; a reference layer 122 on the seed layer 118; an insulator layer 128 on the reference layer 122; a free layer 132 on the insulator layer 128; and a cap layer 136 on the free layer 132.

In one example the substrate layer 110 is silicon wafer with silicon dioxide on the surface of the wafer. In one example the buffer layer 114 includes a first layer of tantalum on the substrate layer 110; a layer of copper nitride on the first layer of tantalum; and a second layer of tantalum on the layer copper nitride layer. In one example, the first and second tantalum layers are each about 5 nm±1 nm thick. The layer of copper nitride is about 15 nm±3 nm thick.

In one example, the seed layer 118 includes alternating layers of ruthenium and copper. In one example, the seed layer is about 14 nm±3 nm thick.

In one example, the reference layer 122 includes a layer of iridium manganese on the seed layer 118; a layer of cobalt iron on the layer of iridium manganese layer; a layer of ruthenium on the layer of cobalt iron; and a layer of cobalt iron boron on the layer of ruthenium. The layer of iridium manganese layer is an antiferromagnetic material and a pinning layer.

The layer of cobalt iron layer is a ferromagnetic material and in some examples is a pinned layer. The layer of ruthenium is a non-magnetic layer and acts as a spacer. The free layer 132 includes a ferromagnetic material (e.g., nickel iron and cobalt iron boron).

In one example, the layer of iridium manganese is about 10 nm±2 nm thick. In one example, the layer of cobalt iron is about 1.7 nm±0.1 nm thick. In one example, the layer of ruthenium is about 0.83 nm±0.01 nm thick. In one example, the layer of cobalt iron boron is about 1 nm±0.1 nm thick.

In one example, the insulator layer 128 is magnesium oxide. In one example, the magnesium oxide is 2 nm±0.1 nm thick.

In one example, the free layer 132 includes a layer of cobalt iron boron on the insulator layer 128; a layer of tantalum on the layer of cobalt iron boron; and a layer of nickel iron on the layer of tantalum. In one example, the layer of cobalt iron is about 1.5 nm±0.1 nm thick. In one example, the layer of tantalum is about an Angstrom thick. In one example, the layer of nickel iron is about 6 nm±0.1 nm thick.

In one example, the cap layer 136 includes a layer of tantalum on the free layer 132; and a layer of ruthenium layer on the layer of tantalum. In one example, the layer of tantalum is about 10 nm±2 nm thick. In one example, the layer of ruthenium is about 10 nm±2 nm thick.

One way to reduce the effects of anisotropy present in antiferromagnetic material and ferromagnetic material is to rotate the substrate during multiple depositions of a layer of antiferromagnetic or ferromagnetic material. For example, after a fraction of material of a layer of magnetic material is deposited, the wafer is rotated, and another fraction of material of the layer of the magnetic material is deposited. The rotation of the wafer and the fractional material deposition continues until the desired thickness of the layer is achieved. This deposition and wafer rotation process is applied to one or more of the magnetic layers in the MR element (e.g., the MR element 100 (FIG. 1)). In one example, after 1/n of the total material of a layer is deposited, the wafer is rotated 360°/n, where n is an integer greater than 1 and n indicates the number of depositions of the material.

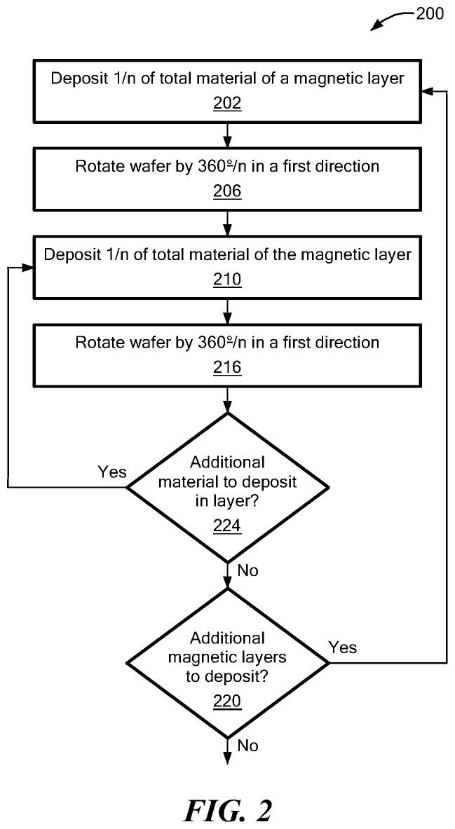

Referring to FIG. 2, an example of a process used to fabricate an angle sensor with reduced angle errors due to orthogonality drift over a magnetic field is a process 200. Process 200 is an example of a process to reduce the effects of anisotropy present in antiferromagnetic material and ferromagnetic material.

Process 200 deposits 1/n of the total material of a magnetic layer (202). In one example, the magnetic layer is a ferromagnetic layer or antiferromagnetic layer such as, for example, one of the layers of the free layer 132 (e.g., the layer of nickel iron or the layer of cobalt iron boron (FIG. 1)) or one of the layers of the reference layer 122 (the layer of iridium manganese, the layer of cobalt iron boron or the layer of cobalt iron (FIG. 1)).

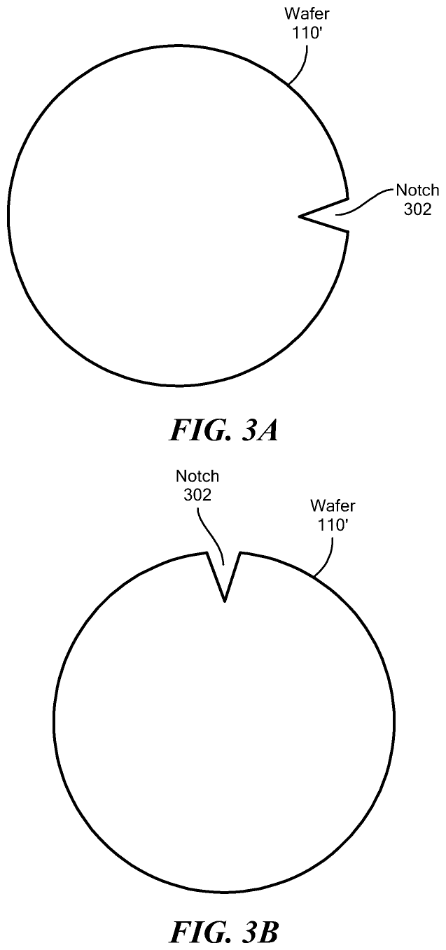

Process 200 rotates wafer 360°/n in a first direction (206). In one example, the first direction is counter-clockwise. In another example, the first direction is clockwise. In one example, n=4 and a wafer 110′ is rotated 90° as depicted from FIG. 3A to FIG. 3B, which is shown by a notch 302 that rotates in counterclockwise direction 90° degrees. In one example, the wafer 110′ is the substrate layer 110 (FIG. 1).

Process 200 deposits 1/n of the total material of the magnetic layer (210) and process 200 rotates the wafer 360°. In one example, n=4 and ¼ of the total material of the magnetic layer is deposited and the wafer 110′ is rotated 90° as depicted by the notch 302 rotating in counterclockwise direction 90° degrees from FIG. 3B to FIG. 3C.

Process 200 determines if there are additional material to deposit in the magnetic layer (224) and if there is additional material to be deposited, process 200 repeats processing blocks 210 and 216 until the desired thickness of the magnetic layer is obtained. For example, when n=4, process 200 deposits another ¼ of the total material of the magnetic layer and rotates the wafer 110′ 90° as shown from FIG. 3C to FIG. 3. Then, process 200 deposits the last deposit of the ¼ of the total material of the magnetic layer and rotates the wafer 110′ 90° as shown from FIG. 3C to FIG. 3D.

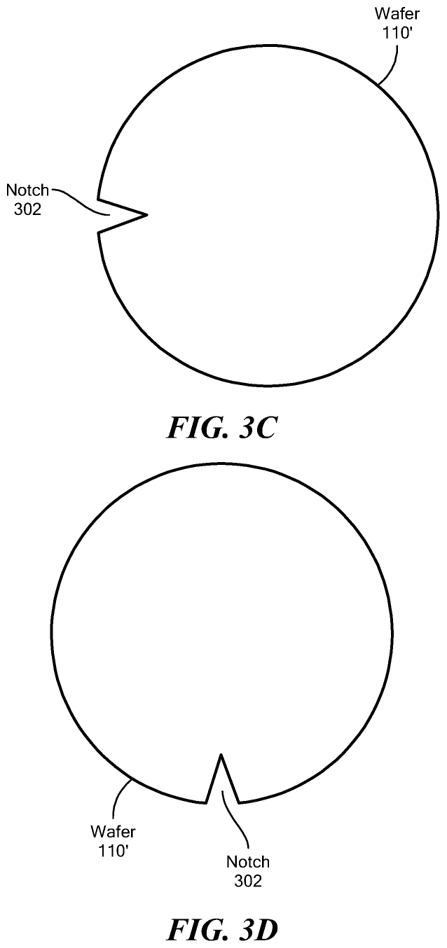

Referring to FIGS. 4A & 4B, process 200 provides a significant improvement in reducing orthogonality errors than the prior art processes. A graph 400 shows a curve 402 that depicts orthogonality errors without using the process 200 where the orthogonality error is greater than 2.25° for a magnetic field less than 300 Oersted (Oe). A graph 450 shows a curve 452 that depicts orthogonality errors using the process 200 which are significantly lower than the prior art shown in FIG. 4A, where the graph 450 shows orthogonality errors less than 0.25° for a magnetic-field less than 300 Oe.

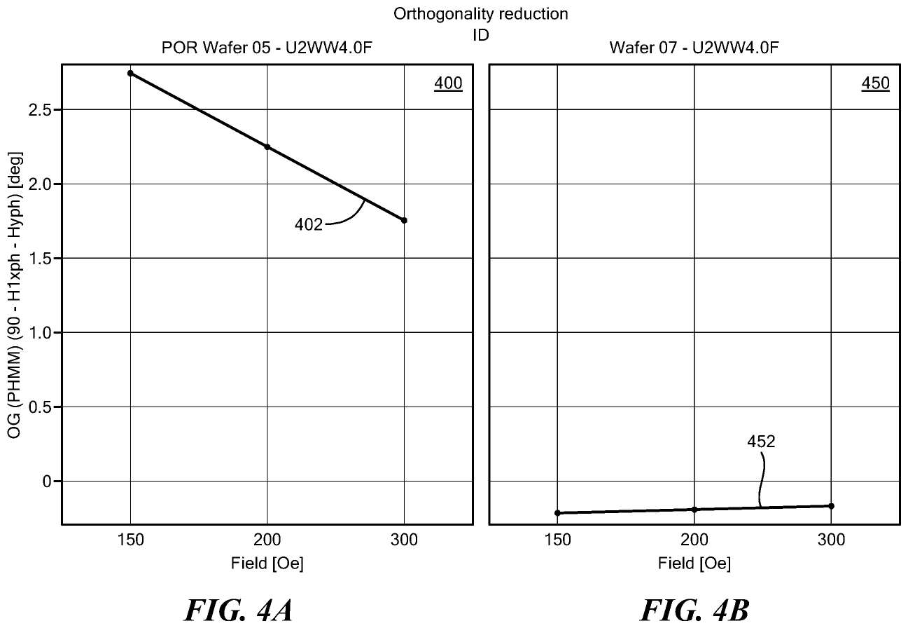

Referring to FIG. 5, another example of a process used to fabricate an angle sensor with reduced angle errors due to orthogonality drift over a magnetic field is a process 500. Process 500 is another example of a process to reduce the effects of anisotropy present in antiferromagnetic material and ferromagnetic material.

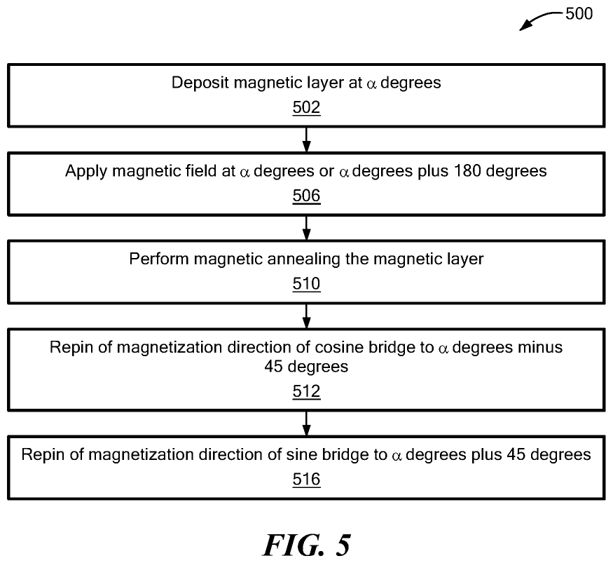

Process 500 deposits a magnetic layer at α degrees (502). In one example, the α degrees is 45° from the notch 302 shown in FIG. 6 that depicts a deposition direction 602.

Process 500 applies a magnetic field at α degrees or α plus 180° (506) and performs magnetic annealing on the magnetic layer (510). For example, a magnetic field is applied in an annealing direction 604 45° from the notch 302 (FIG. 6). In another example, an annealing direction 604 may be 45°+180° or 225° since anisotropy in a magnetic material is uniaxial and not unidirectional.

Process 500 re-pins the magnetization direction of a sine bridge to α degrees minus 45° (512). For example, the MR elements in a sine bridge would each be re-pinned to zero degrees.

Process 500 re-pins the magnetization direction of a cosine bridge to α degrees plus 45° (516). For example, the MR elements in a cosine bridge would each be re-pinned to 90°.

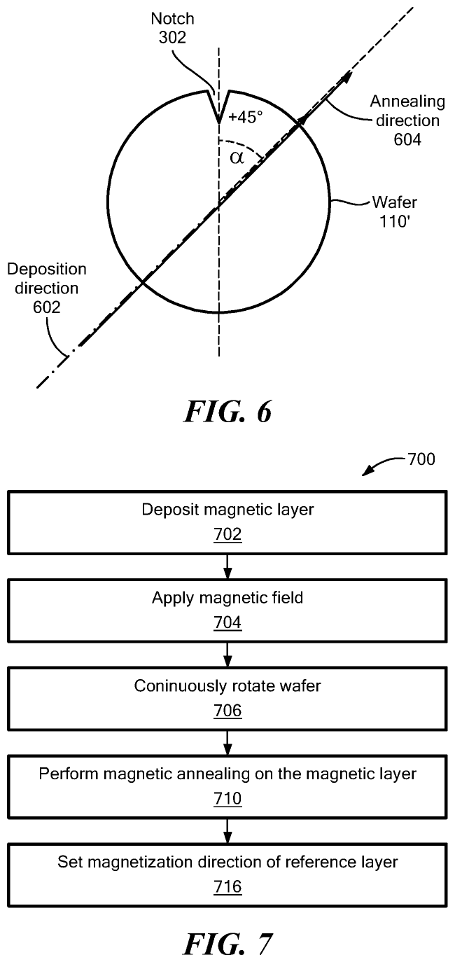

Referring to FIG. 7, a further example of a process used to fabricate an angle sensor with reduced angle errors due to orthogonality drift over a magnetic field is a process 700. Process 700 is a further example of a process to reduce the effects of anisotropy present in antiferromagnetic material and ferromagnetic material.

Process 700 deposits a magnetic layer (702). For example, ferromagnetic or antiferromagnetic material is deposited.

After process 700 deposits the magnetic layer, process 700 applies a magnetic field (704), continuously rotates a wafer (706) and performs magnetic annealing on the magnetic layer (710). For example, the wafer 110′ (FIG. 1) is continuously rotated during a magnetic anneal in the presence of a stationary magnetic field, which will cause any presence of anisotropy from the magnetic layer to disappear. The magnetic field used for the anneal is a large field to overcome all grain orientations (i.e., grains present at the material interfaces as well as in bulk) and any anisotropy present in the system.

Process 700 sets magnetization direction of reference layer (716). Since there is no fixed direction after annealing, an additional anneal processing block is required to set the magnetic field orientation of the reference layer (e.g., the reference layer 122 (FIG. 1)). However, the anisotropy induced by deposition of the magnetic layer is erased because of the rotational anneal.

The processes described herein are not limited to the specific examples described. For example, the processes 200, 500 and 700 are not limited to the specific processing order of FIGS. 2, 5 and 7, respectively. Rather, any of the processing blocks of FIGS. 2, 5 and 7 may be re-ordered, combined, or removed, performed in parallel or in serial, as necessary, to achieve the results set forth above.

In some examples, one or more of the processes (e.g., processes 200, 500 and 700) may be combined. For example, the process 200 may be performed first followed by one or more of the processing blocks in the process 700.

One or more of the processes (e.g., processes 200, 500 and 700) may be used to form one or more MR elements in a sine bridge and/or a cosine bridge of an angle sensor. In one particular example, one or more of the processes (e.g., processes 200, 500 and 700) may be used to form all of the MR elements in a sine bridge and a cosine bridge of an angle sensor.

Having described preferred embodiments, which serve to illustrate various concepts, structures, and techniques, which are the subject of this patent, it will now become apparent to those of ordinary skill in the art that other embodiments incorporating these concepts, structures and techniques may be used.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A method, comprising:
manufacturing a magnetic-field angle sensor on a wafer comprising:
forming a cosine bridge comprising forming a first magnetoresistance (MR) element; and
forming a sine bridge comprising forming a second MR element,
wherein forming the first MR element comprises using a process to reduce orthogonality errors between the sine bridge and the cosine bridge caused by anisotropy present in magnetic material in the first MR element.

2. The method of claim 1, wherein forming the second MR element comprises using the process to reduce the orthogonality errors between the sine bridge and the cosine bridge caused by anisotropy present in magnetic material in the second MR element.

3. The method of claim 1, wherein the process to reduce the orthogonality errors comprises:
depositing 1/n of a total of the magnetic material of a magnetic layer;
rotating the wafer by 360°/n after depositing 1/n of the total of the magnetic material of the magnetic layer;
depositing an additional 1/n of the total of the magnetic material of the magnetic layer after rotating the wafer by 360°/n; and
continuously performing the depositing and the rotating until the total magnetic material is deposited,
wherein n is an integer greater than 2.

4. The method of claim 3, wherein the process to reduce the orthogonality errors further comprises, after depositing the magnetic layer:
rotating the wafer after depositing the magnetic layer; and
performing magnetic annealing of the magnetic layer while the wafer is rotating.

5. The method of claim 1, wherein the process to reduce the orthogonality errors comprises:
depositing a magnetic layer comprising the magnetic material in a first direction;
applying a magnetic field in the first direction; and
performing magnetic annealing of the magnetic layer after depositing the magnetic layer and after applying the magnetic field in the first direction.

6. The method of claim 5, further comprising, after performing magnetic annealing:
re-pinning a magnetization direction of the sine bridge; and
re-pinning a magnetization direction of the cosine bridge.

7. The method of claim 1, wherein the process to reduce the orthogonality errors comprises:
depositing a magnetic layer comprising the magnetic material; and
rotating the wafer after depositing the magnetic layer; and
performing magnetic annealing of the magnetic layer while the wafer is rotating.

8. The method of claim 7, setting a magnetization direction of a reference layer after performing magnetic annealing of the magnetic layer.

9. The method of claim 1, wherein the sine bridge and the cosine bridge each comprises at least four MR elements, and
each MR element in the sine bridge and the cosine bridge are formed using the process to reduce orthogonality.

10. The method of claim 1, wherein the first MR element and/or the second MR element is a giant magnetoresistance (GMR) elements.

11. The method of claim 1, wherein the first MR element and/or the second MR element is a tunneling magnetoresistance (TMR) elements.

12. The method of claim 1, wherein the magnetic material is ferromagnetic material.

13. The method of claim 1, wherein the magnetic material is antiferromagnetic material.
